(19) United States
(12) Patent Application Publication
(10) Pub. No.: US 2011/0004817 A1
(43) Pub. Date: Jan. 6, 2011

(54) CRC MANAGEMENT METHOD PERFORMED IN SATA INTERFACE AND DATA STORAGE DEVICE USING CRC MANAGEMENT METHOD

(75) Inventors: Woo-seong CHEONG, Yongin-si (KR); Tae-min JEONG, Seoul (KR); Sang-kyoo JEONG, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/780,984

(22) Filed: May 17, 2010

(30) Foreign Application Priority Data
Jul. 6, 2009 (KR) 10-2009-0061143

(51) Int. Cl. H03M 13/09; G06F 11/10

(52) U.S. Cl. 714/807; 714/E11.032

(57) ABSTRACT

A cyclic redundancy check (CRC) management method performed in a serial advanced technology attachment (SATA) interface and a data storage device using the CRC management method. A host interface connected to the SATA interface performs CRC computation on transmitted data to generate a first CRC code, determines whether a host interface block error or a data integrity error occurs, or the status of a data storage device needs to be reported to the host interface, generates a second CRC code, which is different from the first CRC code, according to the determination result. If a frame including the transmitted data and the second CRC code is transmitted to a host, the host performs CRC computation on a data FIS in the transmitted data to expect the first CRC code. Since the CRC code in the transmitted data is the second CRC code, the host recognizes that the transmitted data is wrong and provides an error notification to the data storage device. Accordingly, the host can be informed of the host interface block error, the data integrity error, or the status error of the data storage device, not a protocol error in the SATA interface.

### CROSS-REFERENCE TO RELATED APPLICATIONS

This application claims the benefit of Korean Patent Application No. 10-2009-0061143 filed on Jul. 6, 2009, the subject matter of which is hereby incorporated by reference.

### BACKGROUND

The inventive concept relates to data storage devices and methods of operating same. More particularly, the inventive concept relates to cyclic redundancy check (CRC) management methods used when a protocol error does not occur in a serial advanced technology attachment (SATA) interface. The inventive concept also relates to a data storage device using this type of CRC management method.

The SATA interface is one type of conventionally understood storage interface protocol that may be used to effectively connect data storage devices with (e.g.) a host bus. In the SATA interface, a user (or payload) data file is divided into units of up to 8 KB and arranged in a frame information structure (FIS) including corresponding one cyclic redundancy check (CRC) code. The CRC code is derived (i.e., calculated) from the data contents of the FIS and then arranged within at least one of the units. The unit including the FIS and CRC code may then be transmitted to a host via a conventionally understood SATA bus. The receiving host then checks whether an error has occurred in the FIS based on the CRC code. If an error is detected, data transmission to the host is halted and an error notification is returned to a data storage device.

Since the CRC code is derived from the data contents of the FIS, it may be used to detect whether a protocol error has occurred during the transmission via the SATA bus. However, if a CRC error does not occur in the SATA interface but instead occurs in the content of the FIS due to some variation in temperature or power supply voltage in the data storage device, or due to some abnormality in a data transmission path, the content of the FIS in which the error is included is recognized as normal data.

### SUMMARY

The inventive concept provides a cyclic redundancy check (CRC) management method that may effectively be used when a protocol error does not occur in a serial advanced technology attachment (SATA) interface, but instead occurs in some other aspect of the data communication process using the SATA interface.

The inventive concept also provides a data storage device using this type of CRC management method.

According to an aspect of the inventive concept, there is provided a CRC management method performed in a SATA interface between a host and a data storage device, the CRC management method including: determining whether transmitted data includes a header of a data frame information structure (FIS) and a start of frame (SOF) primitive of a data frame to be transmitted to the host and transmitting the transmitted data; performing CRC computation on the transmitted data to generate a first CRC code; if an error is included in the transmitted data, generating a second CRC code that is different from the first CRC code; and selectively carrying the first CRC code or the second CRC code on the transmitted data and transmitting the frame including the transmitted data and one selected from the first CRC code and the second CRC code to the host.

The error included in the transmitted data may be a host interface block error that occurs in internal blocks of a host interface in the data storage device, a data integrity error that occurs along a data path inside the data storage device, an error that occurs during an incorrect operation of internal blocks of the data storage device due to a change in temperature or power supply, or an error that occurs when data of a bad block of a flash memory device used as a storage medium in the data storage device is read out and transmitted to a host interface.

The second CRC code may be generated by adding 1 to the first CRC code or inverting the first CRC code.

According to another aspect of the inventive concept, there is provided a data storage device including: a host interface executing a SATA protocol to communicate with a host, generating a first CRC code and transmitting transmitted data and the first CRC code to the host, and, if an error is included in the transmitted data, generating a second CRC code that is different from the first CRC code and transmitting the transmitted data and the second CRC code to the host; and a storage medium storing or reading data information in the DATA protocol in response to control signals generated from control information and command information that are analyzed by the host interface using the SATA protocol.

### BRIEF DESCRIPTION OF THE DRAWINGS

Embodiments of the inventive concept will be more clearly understood from the following detailed description taken in conjunction with the accompanying drawings in which:

FIG. 1 is a block diagram of a data storage device according to an embodiment of the inventive concept;

FIG. 2 is a conceptual diagram further explaining one possible transmission sequence for a serial advanced technology attachment (SATA) protocol; and

FIG. 3 is a flowchart summarizing a cyclic redundancy check (CRC) management method adapted for use with a SATA interface according to an embodiment of the inventive concept.

### DETAILED DESCRIPTION OF THE EMBODIMENTS

In order to more fully understand operational advantages of the inventive concept and objects attained by embodiments of the inventive concept, the accompanying drawings illustrating exemplary embodiments of the inventive concept and details described in the accompanying drawings should be referred to.

Reference will now be made in some additional detail to certain embodiments of the inventive concept. Throughout the written description and drawings like reference numbers and labels are used to denote like or similar elements.

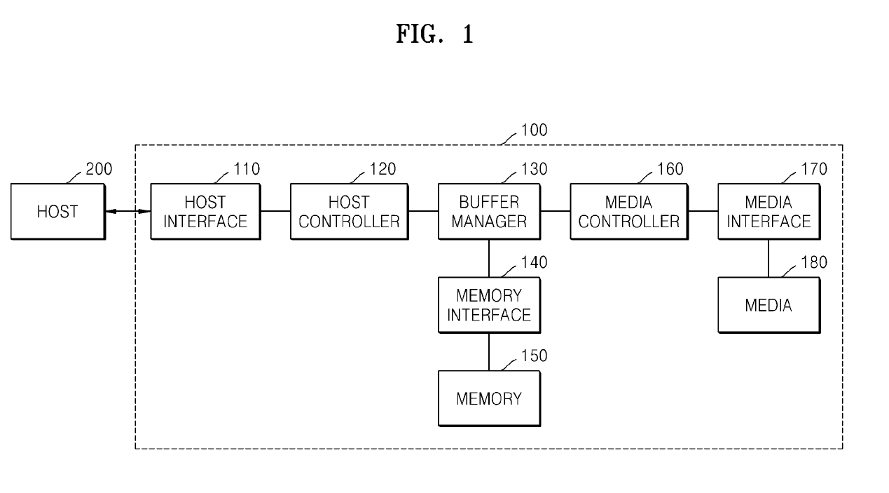

FIG. 1 is a block diagram of a data storage device 100 according to an embodiment of the inventive concept. Referring to FIG. 1, the data storage device 100 comprises a host interface 110, a host controller 120, a buffer manager 130, a memory interface 140, a memory 150, a media controller 160, a media interface 170, and a media 180.

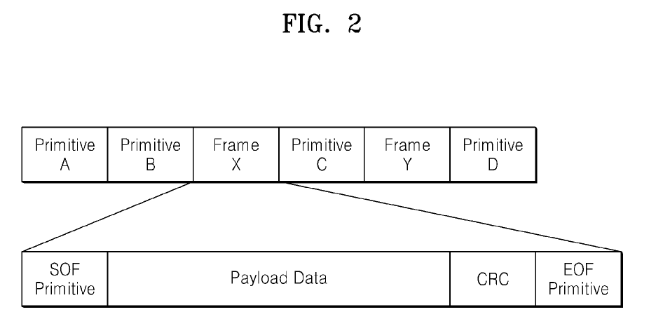

The host interface 110 enables the execution of the conventionally understood serial advanced technology attachment (SATA) protocol. This protocol allows the data storage device 100 to communicate (i.e., exchange data and corresponding control signals) with a host 200. FIG. 2 is a conceptual diagram further explaining one possible transmission sequence that may be used to conjunction with the SATA protocol.

Referring to FIG. 2, certain so-called “primitives” are used to provide real time status information via a serial line connecting the data storage device 100 and the host 200. This real time status information essentially controls the communication of data between the host 200 and the data storage device 100. So-called “frames” are communicated among the primitives include an arrangement of data (e.g., a plurality of double words). For example, in the illustrated embodiment of FIG. 2, each frame begins with a start of frame (SOF) primitive followed by payload data (also referred to as a data FIS) and a cyclic redundancy check (CRC), and ends with an end of frame (EOF) primitive.

Referring back to FIG. 1, the host interface 110 analyzes command and control information in relation to a host to device data frame information structure (FIS) provided as a function of the SATA protocol. Thus, the host interface 110 enables the communication of data (storage device to host, and host to storage device) using the defined FIS. For example, in the illustrated embodiment of FIG. 1, the host interface 110 performs CRC computation on “input data” received from the host 200 to generate a first CRC code, and then compares the first CRC code with a CRC code received from the host 200 to determine whether or not a CRC error has occurred during the communication of the input data. The host interface 110 may similarly control the communication of “output data” along with corresponding first CRC code to the host 200.

For example, if output data including an error (where the error is due to operation of the data storage device 100) is communicated from the data storage device to the host 200, the host interface 110 will derive a second CRC code, instead of the first CRC code previously derived for the data when it was received as input data. This second CRC code is then communicated with the output data to the host 200.

In relation to a defined set of data, the second CRC code may be obtained by adding one (+1) to the first CRC code or inverting the first CRC code. However, the inventive concept is not limited to only these possible methods of deriving the second CRC code.

The host controller 120 generates control signals, such as command or address signals in accordance with the control and command information analyzed by the host interface 110. These control signals are passed to the buffer manager 130.

The buffer manager 130 controls access to the memory 150 using the memory interface 140. The memory 150 is configured to temporarily store the data information of the data-device to host FIS or the data-host to device FIS. The memory 150 may be implemented using one or more conventionally available memory device(s), such as static random access memory (SRAM) or dynamic random access memory (DRAM).

The buffer manager 130 also controls access to the media 180 using the media controller 170 and the media controller 160. The media 180 may be any type of storage medium capable of storing the data information of the data-device to host FIS or the data-host to device FIS. In one embodiment of the inventive concept, the media 180 may be implemented using one or more non-volatile memory device(s), such as flash memory.

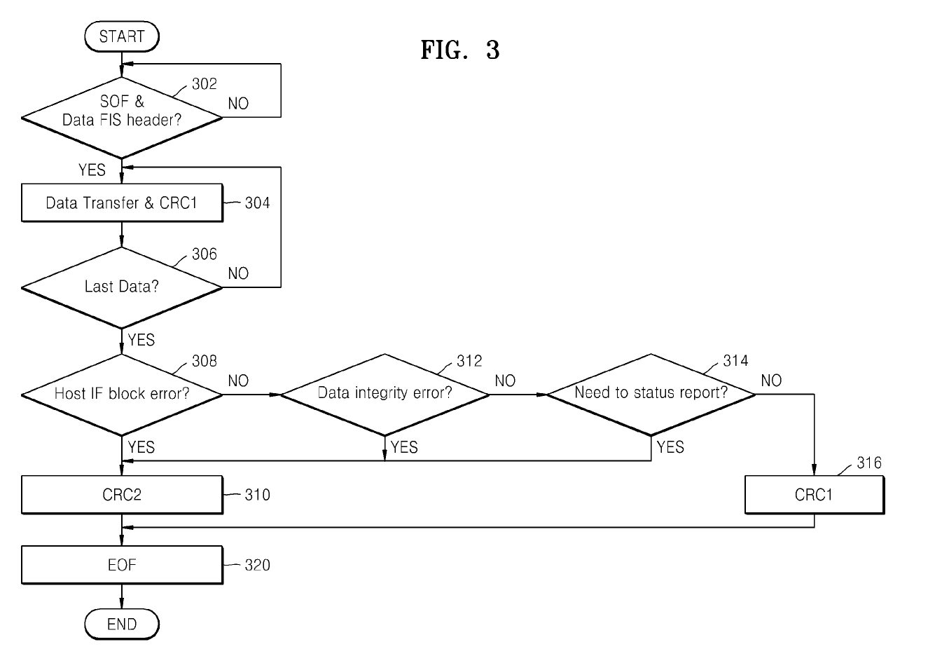

As is conventionally understood, an error may occur during the operation of any one of the elements forming the data storage device 100. That is, any one of the host interface 110, the host controller 120, the buffer manager 130, the memory interface 140, the memory 150, the media controller 160, the media interface 170, and the media 180 may operate or interoperate in such a manner as to generate an error in the data being communicated. In some instances, an error may occur due to some variation in the operating temperature or some variation in the power supply voltage within the data storage device 100. When output data including such an error is communicated to the host interface 110 and then transmitted to the host 200 using the SATA protocol, the data storage device 100 of FIG. 1 may use a CRC management method, such as the one summarized in FIG. 3.

FIG. 3 is a flowchart summarizing a CRC management method performed in a SATA interface according to an embodiment of the inventive concept. Referring to FIGS. 1 and 3, in operation 302, the host interface 110 determines whether transmitted data includes a header of a data FIS and an SOF primitive of a data frame to be transmitted to the host 200. If it is determined in operation 302 that the transmitted data includes the header of the data FIS and the SOF primitive of the data frame to be transmitted to the host 200, the method proceeds to operation 304. In operation 304, the transmitted data is transmitted to the host 200 and the host interface 110 performs CRC computation on the transmitted data to generate a first CRC code CRC1. In operation 306, it is determined whether the transmitted data is last data.

If it is determined in operation 306 that the transmitted data is the last data, the method proceeds to operation 308. In operation 308, it is determined whether a host interface block error occurs in internal blocks of the host interface 110. If it is determined in operation 308 that a host interface block error occurs, the method proceeds to operation 310. In operation 310, the host interface 110 generates a second CRC code CRC 2 that is different from the first code CRC1. In operation 320, the host interface 110 carries an EOF primitive on the transmitted data and transmits the data frame including the transmitted data and the second CRC code CRC2 to the host 200.

If it is determined in operation 308, however, that no host interface block error occurs, the method proceeds to operation 312. In operation 312, the data storage device 100 determines whether a data integrity error occurs on a data path inside the data storage device 100. If it is determined in operation 312 that a data integrity error occurs, the method proceeds to operation 310. In operation 310, the host interface 110 generates the second CRC code CRC2 that is different from the first CRC code CRC1. In operation 320, the host interface 110 carries the EOF primitive on the transmitted data and transmits the data frame including the transmitted data and the second CRC code CRC2 to the host 200.

If it is determined in operation 312, however, that no data integrity error occurs, the method proceeds to operation 314. In operation 314, it is determined whether an error occurs during the operation of internal blocks of the data storage device 100, that is, the host interface 110, the host controller 120, the buffer manager 130, the memory interface 140, the memory 150, the media controller 160, the media interface 170, or the media 180 and it is determined whether the status of the data storage device 100 needs to be reported to the host interface 110. For example, in operation 314, if errors occur during an incorrect operation of the internal blocks of the data storage device 100 due to variation in temperature or power supply voltage, or if errors occur during the operation of the media 180 and data of a bad block in the flash memory device is read out and transmitted to the host interface 110, the status of each of the internal blocks of the data storage device 100 is reported to the host interface 110. In operation 310, the host interface 110 generates the second CRC code CRC2 that is different from the first CRC code CRC1. In operation 320, the host interface 110 carries the EOF primitive on the transmitted data and transmits the data frame including the transmitted data and the second CRC code CRC2 to the host 200.

If it is determined in operation 314, however, that the status of the data storage device 100 does not need to be reported to the host interface 110, the method proceeds to operation 316. In operation 316, the host interface 110 performs CRC computation on the transmitted data to generate the first CRC code CRC1. In operation 320, the host interface 110 carries the EOF primitive on the transmitted data and transmits the data frame including the transmitted data and the first CRC code CRC 1 to the host 200.

Accordingly, according to the CRC management method of FIG. 3, after the host interface 110 performs CRC derivation on the transmitted data to generate the first CRC code CRC1, it is determined whether a host interface block error or a data integrity error occurs, or the status of the data storage device 100 needs to be reported to the host interface 110, and the second CRC code CRC2, which is different from the first CRC code CRC1, is generated according to the determination result. If the data frame including the transmitted data and the second CRC code CRC2 is transmitted to the host 200, the host 200 performs CRC computation on a data FIS in the transmitted data and expects the first CRC code CRC1. Since the CRC code in the transmitted data is the second CRC code CRC2, the host 200 recognizes that the transmitted data is wrong and provides an error notification to the data storage device 100. Accordingly, the host 200 can be informed of the host interface block error, the data integrity error, or the status of the data storage device 100, and not only a protocol error in the SATA interface.

While the inventive concept has been particularly shown and described with reference to embodiments thereof, it will be understood that various changes in form and details may be made therein without departing from the scope of the following claims.

What is claimed is:

1. A cyclic redundancy check (CRC) management method performed in a serial advanced technology attachment (SATA) interface between a host and a data storage device, the CRC management method comprising:
determining whether transmitted data includes a header of a data frame information structure (FIS) and a start of frame (SOF) primitive of a data frame to be transmitted to the host and transmitting the transmitted data;
performing a CRC computation on the transmitted data to generate a first CRC code;
if an error is included in the transmitted data, generating a second CRC code that is different from the first CRC code; and
selectively providing the first CRC code or the second CRC code with the transmitted data and transmitting the frame including the transmitted data and either the first CRC code or the second CRC code to the host.

2. The CRC management method of claim 1, wherein the error included in the transmitted data is a host interface block error occurring in internal blocks of a host interface in the data storage device.

3. The CRC management method of claim 1, wherein the error included in the transmitted data is a data integrity error occurring due to a data path within the data storage device.

4. The CRC management method of claim 1, wherein the error included in the transmitted data is an error occurring due to an incorrect operation of internal blocks of the data storage device arising because of variation in temperature or power supply voltage.

5. The CRC management method of claim 1, wherein the error included in the transmitted data is an error occurring when data of a bad block of a flash memory device used as a storage medium in the data storage device is read and transmitted to a host interface.

6. The CRC management method of claim 1, wherein the second CRC code is generated by adding 1 to the first CRC code.

7. The CRC management method of claim 1, wherein the second CRC code is generated by inverting the first CRC code.

8. A data storage device comprising:
a host interface enabling execution of a SATA protocol to communicate with a host, generating a first CRC code and transmitting transmitted data and the first CRC code to the host, and, if an error is included in the transmitted data, generating a second CRC code different from the first CRC code and transmitting the transmitted data and the second CRC code to the host; and
a storage medium storing/reading data information using the SATA protocol in response to control signals generated from control and command information analyzed by the host interface using the SATA protocol.

9. The data storage device of claim 8, wherein the error included in the transmitted data is a host interface block error occurring in internal blocks of the host interface.

10. The data storage device of claim 8, wherein the error included in the transmitted data is a data integrity error occurring due to a data path within the data storage device.

11. The data storage device of claim 8, wherein the error included in the transmitted data is an error occurring during an incorrect operation of internal blocks of the data storage device due to variation in temperature or power supply voltage.

12. The data storage device of claim 8, wherein the error included in the transmitted data is an error occurring when data of a bad block of a flash memory device used as the storage medium is read and transmitted to the host interface.

13. The data storage device of claim 8, wherein the second CRC code is generated by adding 1 to the first CRC code.

14. The data storage device of claim 8, wherein the second CRC code is generated by inverting the first CRC code.
